(19) United States
(12) Patent Application Publication
(10) Pub. No.: US 2011/0017127 A1
(43) Pub. Date: Jan. 27, 2011

(54) APPARATUS AND METHOD FOR PRODUCING EPITAXIAL LAYERS

(75) Inventors: Hans von Kanel, Wallisellen (CH); Emmanuil Choumas, Werdenberg (CH)

Correspondence Address: MCCORMICK, PAULDING & HUBER LLP, CITY PLACE II, 185 ASYLUM STREET, HARTFORD, CT, 06103, US

(73) Assignee: EpiSpeed SA, Zurich (CH)

(21) Appl. No.: 12/865,501

(22) PCT Filed: Aug. 14, 2008
(86) PCT No.: PCT/EP08/60704

§ 371 Date: Jul. 30, 2010

Related U.S. Application Data
(60) Provisional application No. 60/956,390, filed on Aug. 17, 2007.

(51) Int. Cl. C30B 25/02; C30B 25/10; H01L 21/22; H01L 21/205; C23C 16/448

(52) U.S. Cl. 117/97; 117/103; 117/94; 438/508; 118/723 ER; 257/E21.101; 257/E21.136

(57) ABSTRACT

An apparatus and process for plasma enhanced chemical vapor deposition with an inductively coupled plasma with ion densities above 10¹⁰ cm⁻³ and energies below 20 eV at the substrate enables epitaxial deposition of group IV and compound semiconductor layers at high rates and low substrate temperatures. The epitaxial reactor allows for in-situ plasma cleaning by chlorine and fluorine containing gaseous species.

### FIELD OF THE INVENTION

The invention relates to a reactor and process for epitaxial layer deposition. It applies especially to manufacturing equipment and process for the growth of epitaxial group IV semiconductor layers at substrate temperatures low in comparison to prior art. Examples are epitaxial silicon carbide layers on SiC and silicon substrates, epitaxial Si layers, epitaxial germanium layers and Si₁₋ₓGeₓ alloy layers on silicon substrates, and epitaxial germanium layers on gallium arsenide substrates.

### BACKGROUND OF THE INVENTION

The field of lattice matched epitaxy encompasses homoepitaxy, where a single crystal layer is grown on a single crystalline substrate made from the identical material, or heteroepitaxy, where a single crystal layer is grown on a single crystalline substrate made from a different material but with identical lattice parameter.

The field of lattice mismatched heteroepitaxy concerns growth of a single crystalline film of material I on a single crystalline substrate of material II, whereby materials I and II differ in lattice parameter.

Epitaxial growth can be achieved by a large number of techniques, such as electrochemical deposition, liquid phase epitaxy (LPE), molecular beam epitaxy (MBE), magnetron sputter epitaxy (MSE), and various forms of chemical vapour deposition (CVD), including plasma assisted techniques, such as low-energy plasma-enhanced CVD (LEPECVD). Among these, thermal CVD techniques have so far proven to be most suitable for industrial production of epitaxial structures on a large scale.

In lattice matched epitaxy the main issues calling for low substrate temperatures are the requirements of interface abruptness and sharp doping profiles. The heteroepitaxy of lattice mismatched systems on the other hand involves a number of generic features which are not present in the lattice matched case:
1. Films below a certain thickness can adapt their lateral lattice parameter to that of the substrate, provided that the lattice mismatch is not too large. The films are hence elastically strained, film/substrate interfaces are free from extended defects, and film surfaces are generally smooth. An epitaxial film fully strained to the substrate lattice parameter is often called pseudomorphic. Strain can greatly affect the physical properties of a film.
2. The elastic energy stored in a film increases with its thickness, and eventually becomes too large for pseudomorphic growth to proceed, thus resulting in relaxation of the elastic strain. Depending on the size of the misfit, relaxation can occur in a number of ways:
   a. When the misfit is large, typically above one percent, elastic relaxation is generally observed. This happens by way of surface roughening, for example through island nucleation. This so-called Stranski-Krastanow mechanism results hence in self-organized islands on top of a two-dimensional film, the wetting layer.
   b. For systems with low misfit, strain is preferably relaxed by plastic relaxation, where misfit dislocations are nucleated, once a certain critical thickness is reached.

Usually, island formation and dislocation nucleation are both thermally activated processes. They can therefore be influenced by the choice of substrate temperature during epitaxial growth. Irrespective of the mechanism by which islands are formed, their growth inevitably requires surface diffusion of atoms, which is always thermally activated. In view of these considerations, there is a clear need of lowering the substrate temperature during epitaxy if planar films are desired. Here, “low” means substrate temperatures well below those commonly used for epitaxial growth. This has the undesired consequence that the main method for epitaxial film production, i.e., CVD, becomes very slow, because the reaction rate in CVD is itself thermally activated at low substrate temperatures.

The present invention is of particular relevance for the deposition of group IV semiconductors, where in standard CVD very high substrate temperatures are used. For example in SiC homoepitaxy temperatures are usually above 1500° C. (see for example U.S. Pat. No. 6,641,938 to Landini et al., the entire disclosure of which is hereby incorporated by reference), where problems with susceptor stability arise (see for example U.S. Pat. No. 5,155,062 to Coleman, the entire disclosure of which is hereby incorporated by reference). In standard Si homoepitaxy substrate temperatures are above 900° C. (see for example German Pat. No. DE3525870 to Pozzetti et al., the entire disclosure of which is hereby incorporated by reference).

The heteroepitaxy of Germanium on Gallium Arsenide is an example in which problems arise at high substrate temperatures despite of a good match of the lattice parameters. Here, for temperatures above about 550° C. interfacial interdiffusion occurs, leading to undesirable doping of the Germanium layer. When depositing Ge on GaAs and especially on phosphides lattice matched to GaAs substrates it is also advantageous to initiate growth at low substrate temperature in order to avoid decomposition of the substrate because of its limited thermal stability in UHV. On the other hand, a Ge film may also be intentionally doped close to the interface by diffusion from the substrate upon raising the substrate temperature to above 600° C. during or after growth.

An important example of the lattice mismatched case is Silicon-Germanium heteroepitaxy. Germanium and silicon both crystallize with the diamond structure, and the lattice parameter of Ge exceeds that of Si by about 4%. The two elements are furthermore miscible in any proportion. The lattice misfit between a Si₁₋ₓGeₓ alloy and Si can therefore be varied between 0 and 4% by choosing x. Strain relaxation in a Si₁₋ₓGeₓ film grown epitaxially on a Si substrate has been found to change from plastic to elastic with increasing Ge content. The composition at which the change occurs thereby depends on substrate temperature and deposition rate.

There are several ways in which dislocations can be nucleated and propagate, once the thickness of a strained layer exceeds a certain critical value. In order to act as a misfit dislocation relieving strain, the Burgers vector of a dislocation needs to have an edge component lying in the interfacial plane. As long as the Ge content x is not too large, 60-degree dislocations nucleate at the surface of a Si₁₋ₓGeₓ alloy, forming half-loops which expand by dislocation glide under the influence of the misfit strain. Upon reaching the interface, a half-loop forms a misfit segment in the interfacial plane. The two arms of the half-loop extending to the surface of the film, the so-called threading arms, are driven apart by the force exerted by the misfit strain, whereby the misfit segment elongates, relaxing an increasing portion of the misfit strain (see for example Blakeslee, Mat. Res. Soc. Symp. Proc. 148, 217 (1989), the entire disclosure of which is hereby incorporated by reference).

Many applications call for strain relaxed, flat layers, a requirement which in theory can be satisfied by a network of misfit dislocations. For such a network to form in practice, threading arms would have to move apart all the way to the edges of the substrate onto which the epitaxial film is grown, thus leaving behind pure misfit dislocations in the plane of the interface. Unfortunately, an ideal situation such as this never occurs, since threading arms tend to be blocked by dislocation interactions and other obstacles before the wafer edge is reached.

As a result of dislocation blocking, threading dislocations (TDs) appear at the surface of a relaxed epitaxial film. Since these TDs may affect film properties in a detrimental way, their density should be kept as low as possible. Ways must therefore be found to increase the length of misfit segments, for example by reducing TD blocking, or by avoiding films to relax by the mechanism of dislocation loop nucleation and dislocation glide.

One way to reduce dislocation interaction and thereby reduce TD densities was found to consist of grading the Ge content instead of growing an alloy layer at constant composition. Compositional grading has been shown to work for a number of deposition methods, differing vastly in deposition rate, such as UHV-CVD (see for example U.S. Pat. No. 5,659,187 to Legoues et al., the entire disclosure of which is hereby incorporated by reference), MBE (see for example U.S. Pat. No. 5,221,413 to Brasen et al., the entire disclosure of which is hereby incorporated by reference), and LEPECVD (see for example U.S. Pat. No. 7,115,895 to von Känel, the entire disclosure of which is hereby incorporated by reference).

All prior art techniques have certain disadvantages, however, especially when grading to high Ge contents is required. With the exception of LEPECVD, the throughputs of prior art techniques are very low because of low deposition rates, and necessary layer thicknesses of many micrometers. Moreover, again with the possible exception of LEPECVD, substantial surface roughening has been found, especially when grading to high Ge contents x. These surfaces exhibit a so-called cross-hatch formed by troughs and ridges arranged in a square pattern (see for example Lutz et al., Appl. Phys. Lett. 66, 724 (1995), the entire disclosure of which is hereby incorporated by reference). For example UHV-CVD grown buffer layers graded to pure Ge have exhibited rms surface roughness of 210 nm when grown on on-axis Si(001) substrates. Trenches on the cross-hatched surface were found to be as deep as 600 nm (see for example U.S. Pat. No. 6,039,803 to Fitzgerald et al., the entire disclosure of which is hereby incorporated by reference). The trenches were shown to be associated with pile-ups of threading dislocations because of increased dislocation interaction. Somewhat smoother surfaces and fewer pile-ups were observed on off-cut Si substrates. The rms roughness reached, however, 50 nm even in this case, with the deepest trenches still exceeding 400 nm (see for example U.S. Pat. No. 6,039,803 to Fitzgerald et al., the entire disclosure of which is hereby incorporated by reference). Surface roughening at high Ge contents is hard to control in CVD also because substrate temperatures above 700° C. are generally required to promote dislocation motion (and with it, strain relaxation) at the start of the grading, i.e., at low Ge content, whereas this is no longer the case at high Ge contents. Changing the substrate temperature during growth is, however, disadvantageous for most CVD techniques because of strong temperature dependence of deposition rate and Ge incorporation.

In order to improve the surface quality and lower the threading dislocation density, an intermediate chemical-mechanical polishing step after grading to x=0.5 was therefore found to be necessary (see for example U.S. Pat. No. 6,107,653 to Fitzgerald, the entire disclosure of which is hereby incorporated by reference).

One of the main problems of prior art approaches based on graded buffer layers is that the large layer thicknesses involved, together with different thermal expansion coefficients, favour crack formation upon cooling from the growth temperature to room temperature (see for example Yang et al., 3. Appl. Phys. 93, 3859 (2003), the entire disclosure of which is hereby incorporated by reference).

The dislocation structure of pure Ge layers deposited directly onto Si substrates has been found to be distinctly different from the one of Si₁₋ₓGeₓ alloy with low Ge content. Here, a network of interfacial 90-degree dislocations was revealed in annealed films grown by hydrogen-surfactant MBE at substrate temperatures of 200° and 300° C. (see for example Sakai et al., Appl. Phys. Lett. 86, 221916 (2005), the entire disclosure of which is hereby incorporated by reference).

Using atmospheric pressure CVD to first deposit a Ge base layer at low substrate temperature (400-500° C.), and then a second Ge layer at higher temperature(750-850° C.), one micrometer thick Ge layers with surprisingly low defect densities could be grown (see for example U.S. Pat. No. 6,537,370 to Hernandez et al., the entire disclosure of which is hereby incorporated by reference). These layers were, however, again rough and needed chemical mechanical polishing. Moreover, as grown layers were found to be compressively strained and had to be annealed before chemical-mechanical polishing.

A closely related approach was described by Luan et al., using UHV-CVD at much lower growth rates (see Luan et al., Appl. Phys. Lett. 75, 2909 (1999), the entire disclosure of which is hereby incorporated by reference). In this case, a threading dislocation density of 2.3×10⁷ cm⁻² was observed on 1 μm thick Ge films after repeated temperature cycling. A similar, equally slow procedure with low-pressure CVD was shown to result in smooth surfaces, with rms roughness as low as 0.5 nm (see for example Colace et al., Appl. Phys. Lett. 72, 3175 (1998), the entire disclosure of which is hereby incorporated by reference).

In previous art, LEPECVD was shown to be superior to other techniques for epitaxial SiGe deposition in terms of speed and flexibility in the choice of substrate temperatures. LEPECVD has been proven to yield high-quality graded Si₁₋ₓGeₓ layers (see for example U.S. Pat. No. 7,115,895 to von Känel, the entire disclosure of which is hereby incorporated by reference), and pure epitaxial Ge layers (see for example International Patent Application No. WO2005/108654 to von Känel, and von Känel et al., Jap. J. Appl. Phys. 39, 2050 (2000) the entire disclosure of which is hereby incorporated by reference). In contrast to other CVD techniques, neither the growth rate nor the alloy composition changes appreciably when the substrate temperature is varied in the range between 200 and 700° C.

In this previous art, the dense, low-energy plasma used in LEPECVD was generated by a low-voltage DC arc discharge as described for example in U.S. Pat. No. 6,454,855 to von Känel et al., the entire disclosure of which is hereby incorporated by reference.

Systems using a DC arc discharge for plasma generation are hard to scale to large substrate sizes of 300 mm and beyond, because a uniform plasma is very difficult to achieve over an area of this size. There have been attempts to improve plasma uniformity by replacing the original point source (see for example U.S. Pat. No. 6,454,855 of von Känel et al., the entire disclosure of which is hereby incorporated by reference) by a broad-area source as described for example in the International Patent Application No. WO2006/000846 to von Känel et al., the entire disclosure of which is hereby incorporated by reference. The use of a DC source does, however, have additional disadvantages. There are for example, metallic parts, such as a metallic cover of the plasma source, and thermionic emitters in direct contact with the plasma, and hence also with corrosive gases during a cleaning cycle. The same applies to the anode, in case that an anode is used, or to the metallic chamber walls in case of an anode-less design. These features are difficult or impossible to reconcile with in-situ plasma chamber cleaning for reasons of materials compatibility. They therefore increase hardware design complexity, thus raising costs, Hardware degradation affects process reproducibility, leads to chemical memory effects and finally to contamination during a deposition cycle. Chamber cleaning is, however, indispensable in order to avoid particulate contamination and undesirable doping of epitaxial films. Moreover, the thermionic emitters used to sustain the DC arc discharge are a potential source of metal contamination in the growing film.

The described disadvantages are absent when an RF plasma is used instead of a DC plasma. ICP sources have for example been shown to yield very uniform plasmas suitable for etching 300 mm wafers (see for example Collison et al., J. Vac. Sci. Technol. A 16, 100 (1998), the entire disclosure of which is hereby incorporated by reference). Furthermore, there are no metallic parts whatsoever in direct contact with the plasma. Reactor cleaning can therefore be achieved much more easily, in the absence of corrosion of any metal parts. This facilitates hardware design and reduces complexity and costs. Eliminating hardware degradation dramatically reduces cost of ownership of an RF plasma system.

For Si-based semiconductors it has been shown that ion energies have to be kept below about 15 eV when defect-free epitaxy is to be achieved on a wafer scale at low substrate temperatures (see for example U.S. Pat. No. 6,454,855 to von Känel et al., the entire disclosure of which is hereby incorporated by reference). One type of RF plasma source which can be operated in order to meet this requirement is manufactured by CCR Technology, Germany, and described for example in U.S. Pat. No. 6,936,144 to Weiler et al., the entire disclosure of which is hereby incorporated by reference. The corresponding matching network has been described for example in U.S. Pat. No. 7,276,816 to Weiler et al. the entire disclosure of which is hereby incorporated by reference. This kind of plasma source and matching network exhibits a feature of special relevance to the epitaxy of Si-based semiconductors. The RF-power applied to the source can be changed without affecting the ion energies and without readjustment of the matching network. This makes it possible to vary the flux of low-energy ions incident on the surface over a wide range (from tens of μA/cm² to several mA/cm²). Intense bombardment by low-energy ions is expected to affect the morphology and strain state of an epitaxial film without leading to ion-induced damage. In particular, low-energy ion bombardment may enhance dislocation mobility and hence lead to a reduction of the threading dislocation density in relaxed epitaxial films. This suggests that the often desired reduction of the thickness of a relaxed film can be achieved by tuning the flux of low-energy ions impinging on the surface during growth.

It is one of the objects of the present invention to provide an epitaxy system and modes of operation of RF plasma sources such as those manufactured by CCR Technology in order to permit semiconductor epitaxy on a wafer scale with low defect density.

It is one of the objectives of the present invention to provide a manufacturing system for epitaxial semiconductors, which combines scalability with the ability to obtain high deposition rates at substrate temperatures low in comparison to those used in prior art. This simplifies equipment design, and allows better control over doping profiles, interface abruptness and planarity, as well as material stability, and any effects associated with lattice strain.

It is another object of the present invention to devise a production apparatus and process for epitaxial film deposition, which does not suffer from any growth rate limitations upon lowering the substrate temperature.

It is yet another object of the present invention to devise means for reducing thermal mismatch strain, thereby greatly enhancing the usable range of epitaxial layer thicknesses.

It is yet another object of the present invention to provide a system for Ge heteroepitaxy on Si or GaAs substrates, allowing epitaxial growth at very low substrate temperatures as low as 200° C., while maintaining high rates above 1 nm/s.

It is yet another object of the present invention to devise an epitaxial semiconductor manufacturing system for group IV semiconductors devoid of any metal parts in direct communication with the epitaxial reactor, which is scalable to large substrate sizes and compatible with in-situ plasma cleaning. A related manufacturing system, adapted to epitaxial deposition of compound semiconductor layers, has been described in International Patent Application No. WO2006/097804 to von Känel.

The present invention is applicable also to compound semiconductor epitaxy, using metal organic and hydride gases customary in metal organic chemical vapour deposition.

### SUMMARY OF THE INVENTION

The present invention concerns an apparatus and process for low-energy plasma enhanced chemical vapour deposition using inductively coupled plasma sources providing ion energies below 20 eV at the substrate position. The epitaxial reactor is compatible with in-situ plasma cleaning by chlorine or fluorine containing gases. Apparatus and process apply especially to the epitaxial deposition of group IV layers and heterostructures, such as SiC homoepitaxy, SiC heteroepitaxy on Si, Si homoepitaxy, Si₁₋ₓGeₓ heteroepitaxy on Si, and Ge heteroepitaxy on GaAs substrates. They can, however, be applied also to the deposition of compound semiconductor layers, when metal organic gases are used together with hydrides of group V elements.

The apparatus is designed such as to permit high ion densities above 10¹⁰ cm⁻³ at the substrate position, whereby process gases are highly excited and made more reactive, such as to allow substantial lowering of the substrate temperature during deposition with respect to those customary in pure thermal chemical vapour deposition.

### BRIEF DESCRIPTION OF THE DRAWINGS

FIG. 1A: Layout of an epitaxial deposition system with ICP coils and spiral antenna, in accordance with the present invention;

FIG. 1B: Structural view of a fast gas switching system;

FIG. 2: Arrangement of coils for shaping the plasma, in accordance with the present invention

FIG. 3: An inventive process flow for low-energy plasma-enhanced chemical vapour deposition;

FIG. 4: Layout of an epitaxial deposition system with ICP spiral antenna, in accordance with the present invention;

FIG. 5: Layout of an epitaxial deposition system with ICP coils, in accordance with the present invention;

FIG. 6: Layout of an epitaxial deposition system with alternative wafer loading, in accordance with the present invention.

### DESCRIPTION OF PREFERRED EMBODIMENTS

### First Embodiment of the Invention

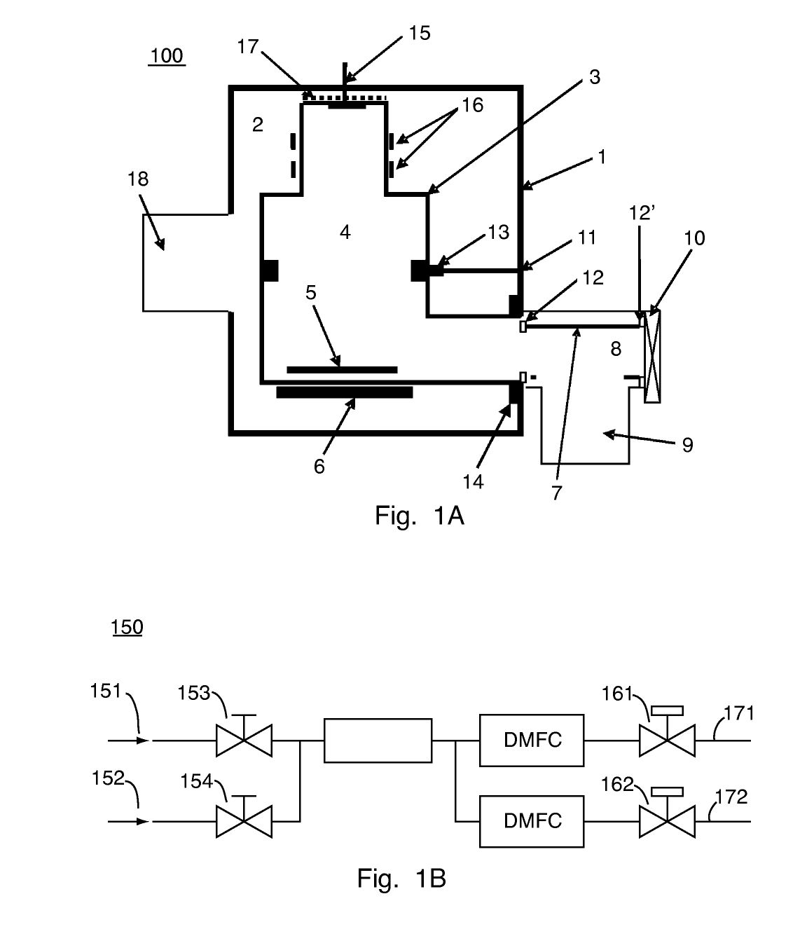

FIG. 1A shows a schematic representation 100 of a first embodiment of the present invention. A metallic vacuum vessel 1 encloses a vacuum chamber 2 connectable to a vacuum pump 18, for example a turbomolecular pump. Vacuum pump 18 permits evacuating the chamber 2 to pressures below 10-6 mbar, preferably even to pressures below 10-8 mbar. The vacuum chamber 2 contains an insert 3 (also called quartz enclosure), which does not contain any metallic parts. Insert 3 is made from quartz or a ceramic material or from a material coated by a ceramic or by graphite, for example, and encloses the entire deposition region 4 or defines a deposition region 4. This prevents any reactive gases employed inside the deposition region 4 to get into contact with the metallic vacuum vessel 1. A susceptor 5 carrying a substrate is preferably located on a bottom of chamber 4 with the substrate facing up. The substrate is heated radiatively (that is indirectly) from the back by a heater 6 located outside the enclosure 3. Alternatively, the substrate may be heated by an induction heater. The deposition region 4 is a hot region which is separated dynamically by a gas insulation ring 12 from a cold reactor part 8, e.g. enclosed by a quartz vessel 7. A similar gas insulation ring 12′ also separates the cold reactor part 8 from a gate valve 10, whereby the gate valve 10 is protected against corrosive gases. The deposition region 4 and the cold reactor region 8 are pumped by a high capacity vacuum pump 9, for instance. Thereby, the gas insulation rings 12, 12′ are kept under continuous flow during operation. This ensures negligible back streaming of impurities from the cold reactor part 8 back into the hot deposition region 4 of the reactor. Differential pumping of the vacuum vessel 1 by the pump 18 ensures that no plasma can be ignited in the low pressure region 2, keeping the vessel 1 clean.

The complete quartz enclosure 3 of the reactor requires only few seals at the gas injection points 13, 15, the pressure gauges (not shown), and the quartz to metal seals 14 close to the pump 9. The gas ring 12 separating the hot deposition region 4 from the cold reactor part 8 of the reactor also helps to throttle total reactor volume, thereby ensuring lower pressure gradients in the system.

An inductively coupled plasma (ICP) source is employed which may optionally comprise an assembly of coils 16 and/or a spiral antenna 17, both located in the vacuum chamber 2 outside the quartz enclosure 3. Gases for the plasma source are introduced through a gas inlet 15. For example He, Ar, H2 or mixtures of these gases may be used to feed the plasma source. The gas mixtures may be provided by a fast gas switching system 150 as shown on FIG. 1B comprising a gas inlet with gas lines 151, 152 for reactive and/or inert gases. For rapid switching, high and low capacity digital mass flow controllers DMFC are connected in parallel. A steady gas flow is maintained through the digital mass flow controllers DMFC in order to avoid overshoots during switching. This is accomplished by gas-to-process-chamber, and gas-to-bypass valves 161 and 162 respectively, by means of which the gas flows can be directed into one of the outlet lines 171, 172. The fast gas switching system 150 further comprises main inlet valve 153 and purge valve 154. The plasma source may be operated at a frequency of 13.56 MHz or any other frequency. Especially lower frequencies have been found to be suitable because of reduced capacitive coupling effects. The capacitive coupling component is mainly responsible for increasing the ion energy in the plasma. The bombardment of the substrate during epitaxy should, however, be limited to ions with energies below the threshold for ion damage. For example for Si homoepitaxy ions with energies below 15 eV have been found to be adequate (see for example U.S. Pat. No. 6,454,855 to von Känel et al., the entire disclosure of which is hereby incorporated by reference).

The coils 16 and 17 may also be operated at two different frequencies, for example one of them at 13.56 MHz or above and the other at 2 MHz or below.

During plasma processing reactive gases are supplied through gas inlet 11 and distributed by a gas distribution ring 13, preferably made from fused quartz. The reactive gases can be hydrogen for wafer cleaning and as additive for layer deposition; silane and other Si containing gases for Si deposition; germane and other Ge containing gases for Ge deposition; mixtures of Si and Ge containing gases for Si₁₋ₓGeₓ alloy deposition; methane and other C containing gases for diamond-like layer deposition; mixtures of Si and C containing gases for SiC deposition; and mixtures of Si, Ge and C containing gases for the deposition of Si_{1-x-y}GeₓC_{y} alloy layers. In addition, doping gases such as diborane, arsine, phosphine, and other gases containing elements suitable for doping group IV semiconductors, may be supplied through the gas inlet 11. The doping gases may be supplied in suitably diluted form, for example by diluting with H₂, Ar or He. Preferably, the reactive gas mixtures are supplied by the fast gas switching system 150. This, together with an optional rapid change of the power supplied to the ICP source, has the advantage of allowing precise control over layer thicknesses at a monolayer scale.

Introducing the reactive gases through a gas distribution ring 13 close to the susceptor 5 has the advantage of improved gas utilization in comparison to supplying reactive gases through the gas inlet 15 of the plasma source.

It has the further advantage of lowering the ion energies because of thermalization by additional scattering in a region of locally increased pressure close to the substrate.

The application of the inventive scheme 100 can be extended to the epitaxial deposition of compound semiconductor layers, by using metal organic gases such as trimethyl gallium, trimethyl aluminium or trimethyl indium, along with nitrogen, arsine or phosphine.

Alternatively, cleaning gases such as Cl₂, NF₃, H₂ and other chlorine or fluorine containing gases may be supplied through the gas distribution ring 13 during reactor cleaning in a low-energy plasma generated by the coils 16 and 17.

The quartz/ceramic enclosures 3, 7 may optionally be provided with additional heaters (not shown) in order to facilitate the desorption of impurities from their inner walls.

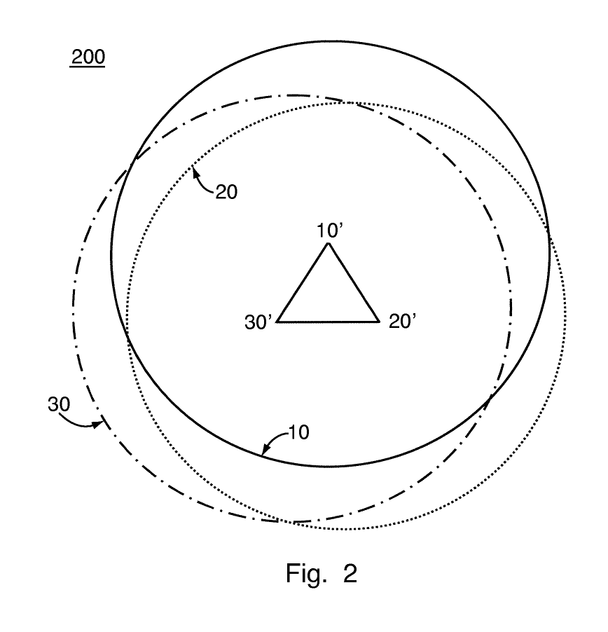

Optionally, an arrangement of coils may be provided outside the enclosures 1 or 3 for shaping the plasma generated by plasma sources 16, 17. An arrangement 200 which was found to be particularly adequate for correcting non-uniformities of the plasma in case of large substrate sizes is shown in FIG. 2. Here, three flat coils 10, 20, 30, are arranged in an off-centered configuration, the centers of the coils 10, 20, 30 being located at positions 10′, 20′ and 30′. The coils 10, 20, 30 can be powered with three different electrical DC currents to adjust the optimum distribution of the plasma. Additionally, three low frequency AC currents with appropriate phase shifts may be applied to coils 10, 20 and 30, whereby a rotational component of the B-field can be generated. Furthermore, two sets of planar coils, one of which is shown in FIG. 2, can be arranged in a Helmholtz or Maxwell configuration.

Even more degrees of freedom for shaping the magnetic field, and with it the plasma distribution, can be obtained by using elliptical instead of circular coils, and by tilting them with respect to the plane shown in FIG. 2.

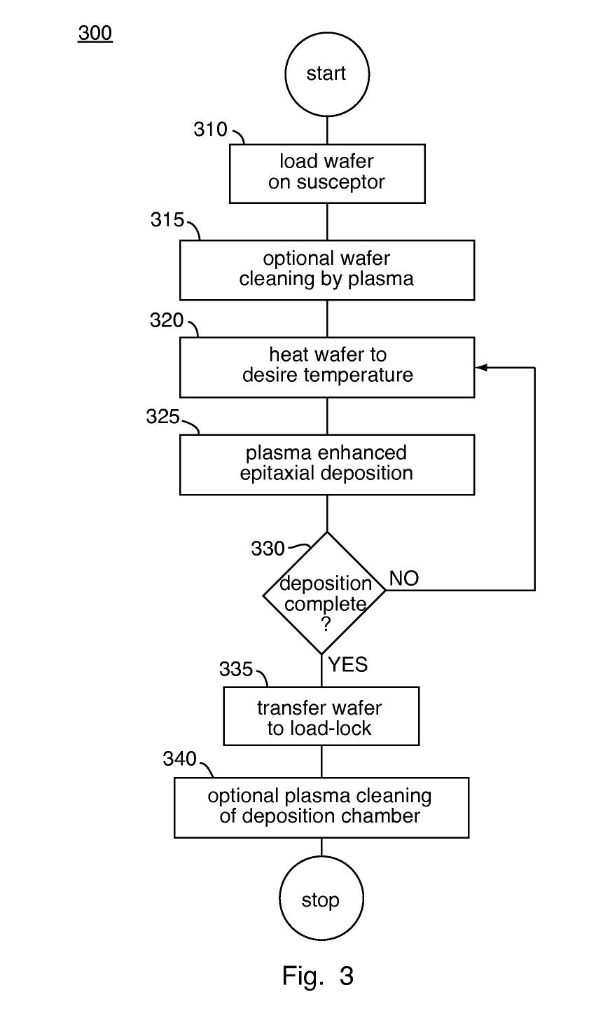

An inventive process 300 of semiconductor epitaxy using the system 100 of FIG. 1A will now be described by reference to FIG. 3. In a first step 310 a wafer (serving as substrate) is transferred from the load-lock through the gate valve 10 onto the susceptor 5 heated to some stand-by temperature T₁. In an optional step 315 the wafer may be subjected to a low-energy plasma cleaning procedure, for example by hydrogen gas introduced through the gas inlet 11 and dispersed by the gas distribution ring 13. The frequency and power supplied to the ICP coils, and the pressure in region 4 close to the substrate are preferably chosen such as to guarantee ion energies during plasma cleaning below about 20 eV, preferably even below 15 eV at a density of at least 10¹⁰ cm⁻³ at the wafer surface. This assures high activation of the cleaning gases, while avoiding damage of the substrate by ion bombardment.

The temperature of the wafer is then adjusted according to the appropriate epitaxy temperature T₂ in step 320. In a low-energy plasma-enhanced chemical vapor deposition step 325 a semiconductor layer is grown epitaxially by supplying the appropriate gas mixture through the gas distribution ring 13. During epitaxial deposition the pressure in the deposition region 4 is preferably kept in the range of 10⁻⁴ to 10⁻¹ mbar. The frequency and power supplied to ICP coils 16, 17 is preferably chosen such as to guarantee a density of low-energy ions of at least 10¹⁰ cm⁻³ at the wafer surface. Here, low-energy ions means ions with energies not exceeding 20 eV, with energies below 15 eV or even below 10 eV being more suitable for defect-free epitaxial growth, since surface bombardment by low-energy ions does not result in any damage. The lowest energies can be achieved by keeping the pressure in the substrate region above 10⁻² mbar or preferably even 10⁻¹ mbar, by introducing sufficient gas through the distribution ring 13. This allows the plasma source to be operated close to pure dissociation mode, where the fraction of ions becomes negligible with respect to neutral radicals. A high partial pressure of reactive gases in the deposition region 4 also has the advantage of allowing high deposition rates. For example a total pressure of about 3×10⁻² mbar generated by a silane/germane mixture introduced through gas distribution ring 13 and pure argon or another noble gas through the source inlet 15 has been shown to be adequate for a deposition rate of 5-10 nm/s. Here, the pressure reading has been taken at a distance of about 30 cm from gas distribution ring 13, before turning on the plasma. For example for a reactor designed for the processing of 100 mm wafers, these values can be reached at a total reactive gas flow of 40 sccm and an argon flow of 50 sccm, respectively. For larger reactors correspondingly higher gas flows will have to be employed. In step 330 the decision is taken whether epitaxial layer growth is complete. If not, step 320 may be repeated by changing the substrate temperature to some value T₃ suitable for further epitaxial growth 325. Alternatively, steps 320 and 325 may also be combined by changing the substrate temperature continuously or in a step-wise fashion during epitaxial growth.

Upon termination of epitaxial growth, the substrate temperature is changed to a value T₄ suitable for wafer transfer, and the wafer is transferred to the load-lock through the gate valve 10 in step 335. In an optional cleaning step 340 the interior 4 of the enclosure 3 may then be exposed to a reactive plasma containing hydrogen, fluorine or chlorine species. The plasma cleaning step 340 is preferably carried out at chamber pressures in between 10⁻³ and 1 mbar, achieved by reactive gas flows 1 to 100 times as large as the flows suitable for epitaxial deposition. This has the advantage of fast etching of deposits from the walls of enclosure 3, the susceptor 5 and the gas distribution ring 13. After plasma cleaning with fluorine or chlorine containing species it is advisable to clean the epitaxial reactor additionally with a pure hydrogen plasma.

It is further advisable to pre-coat the interior of the enclosure 3 prior to the next deposition step in order to passivate O₂, F and Cl impurities.

### Second Embodiment of the Invention

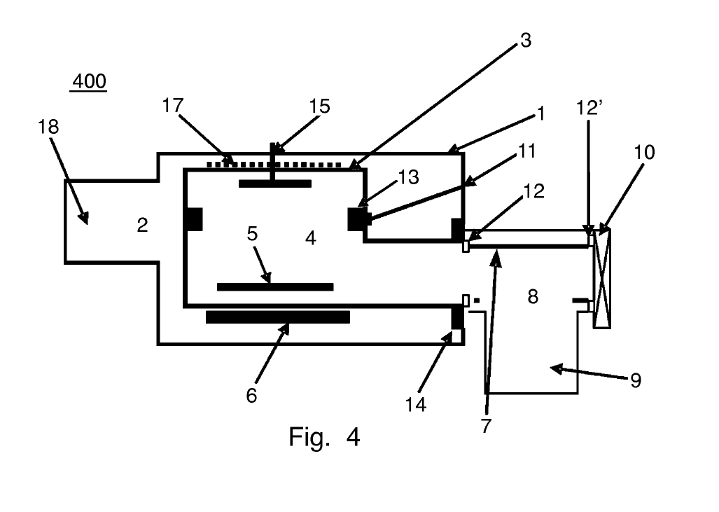

FIG. 4 shows a schematic representation 400 of a second embodiment of the invention. In this embodiment, the low-energy plasma is generated exclusively by an ICP spiral antenna 17, allowing a more compact design than that of representation 100. The spiral antenna 17 may be excited either at one single frequency, or simultaneously at two frequencies, such as for example at 13.56 MHz or above and at 2 MHz or below. The same reference numbers are used as in connection with FIG. 1 for components and elements which are essentially the same.

### Third Embodiment of the Invention

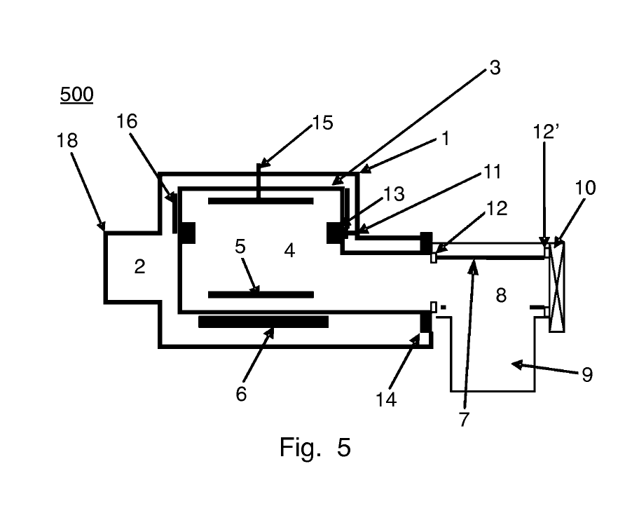

A schematic representation 500 of a third embodiment of the invention is shown in FIG. 5. In this embodiment, the low-energy plasma is generated exclusively by an ICP coil 16 wound around the enclosure 2. The ICP coil 16 may be excited either at one single frequency, or simultaneously at two frequencies, such as for example at 13.56 MHz or above and at 2 MHz or below. The same reference numbers are used as in connection with FIG. 1A for components and elements which are essentially the same.

### Fourth Embodiment of the Invention

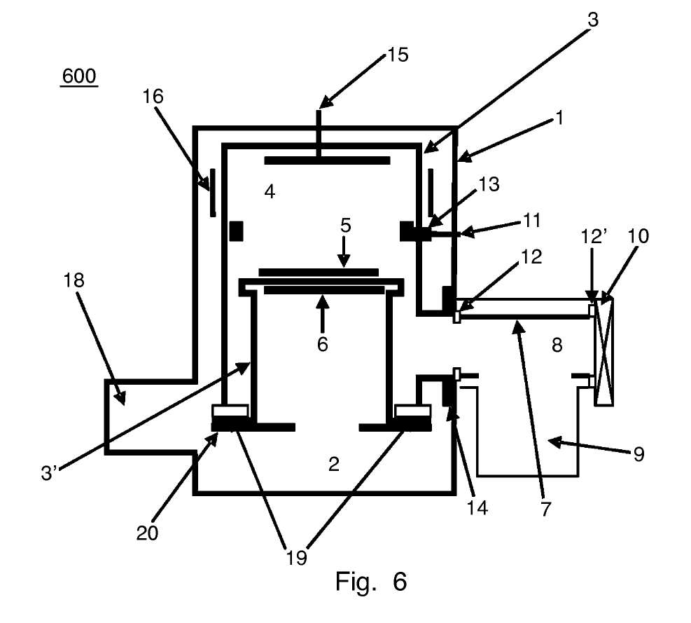

A schematic representation 600 of a fourth embodiment of the invention is shown in FIG. 6. In this embodiment, the enclosure of the deposition region 4 consists of two parts 3, 3′, separated by a gas insulation ring 19. Enclosure 3′, together with a heater assembly 6 and a susceptor 5, is supported by a movable base plate 20. The movable enclosure 3′ results in additional degrees of freedom for wafer loading. Instead of loading through a gate valve 10 adjacent to a pump 9, the wafer may be loaded from another side of the vacuum chamber 1 (not shown). Dividing the enclosure of the reactor 4 into two parts 3, 3′, does require an additional gas insulation ring 19 between part 3 and part 3′.

The present invention is applicable to any epitaxial layer/substrate combinations in which lowering the substrate temperature without loss of growth rate and/or decrease of layer quality is desirable, as is typically the case for chemical vapour deposition processes. Thereby, it should be understood that the term “low substrate temperature” depends on the material system, and therefore cannot be specified by a single number.
According to the present invention, for example for SiC homoepitaxy, lowering the substrate temperature from 1500-1600° C. to below 1200° C. will bring great benefits in terms of reactor simplification, because of fewer wear problems. Applications of SiC homoepitaxy are for example found in high temperature, high power electronics.
According to the present invention, the SiC heteroepitaxy on Si substrates may be carried out at temperatures below 1000° C. Epitaxial SiC layers on Si serve for example as templates for GaN epitaxy.
In Si homoepitaxy, dopant interdiffusion becomes less and less significant, as substrate temperatures are lowered to below 800° C. The present invention enables the Si homoepitaxy at temperatures below 800° C. Any microelectronic devices requiring sharp dopant profiles have to be processed at such low substrate temperatures.
According to the present invention, in SiGe heteroepitaxy on Si surface roughness is greatly reduced, especially for Ge-rich layers. For layer compositions close to pure Ge temperatures below 500° C. may be highly advantageous. SiGe heterostructures on Si substrates are used for integrated optics applications, including waveguides, modulators, detectors, and quantum cascade lasers. Low substrate temperatures are required especially for monolithic integration with Si CMOS electronics.
According to the present invention, in Ge heteroepitaxy on GaAs substrates or on other I-V semiconductors lattice matched to GaAs, undesirable doping by interdiffusion can be eliminated for substrate temperatures below 500° C. Epitaxial Ge films on GaAs and InGaP find application for example in high-efficiency solar cells, together with layer transfer techniques.
According to the present invention, in pure Ge heteroepitaxy on Si substrate temperatures as low as 200° C. may be required to suppress surface roughening by the Stranski-Krastanow process. Applications of pure epitaxial Ge layers on Si substrates are detectors for infrared and X-ray radiation, integrated with Si CMOS electronics.

1. Reactor (100; 400; 500; 600) for low-energy plasma-enhanced chemical vapour deposition of an epitaxial semiconductor layer on a semiconductor substrate, comprising
a metallic vacuum vessel (1) enclosing a vacuum chamber (2) connectable to a vacuum pump (18) for evacuating the vacuum chamber (2),
an enclosure (3), preferably a quartz or ceramic enclosure, contained inside said vacuum vessel (1), for defining a hot deposition region (4) inside the enclosure (3),
an enclosure (7), preferably a quartz or ceramic enclosure or an enclosure coated by a ceramic material or graphite, for defining a cold region (8) adjacent to said hot region (4) with a gate valve (10),
a vacuum pump (9) for pumping said hot deposition region (4) and said cold region (8),
gas insulation rings (12, 12′) to dynamically separate said hot deposition region (4) from said cold region (8) and said cold region (8) from said gate valve (10), to protect said gate valve (10) from corrosive gases and to lower the pressure gradient between said hot region (4) and said cold region (8),
a susceptor (5) carrying said substrate, said susceptor (5) being located inside said enclosure (3),
means (6) for indirectly heating said substrate,
sealed gas injection points (13, 15) in said enclosure (3) for feeding gases into said deposition region (4),
an inductively coupled radio-frequency (RF) plasma source comprising a coil (16) and/or a spiral antenna (17), both located outside the quartz enclosure (3),
wherein the power and frequency supplied to the coil (16) and/or the spiral antenna (17), and the pressure in said deposition region (4) are adjusted to provide
ion energies below about 20 eV, preferably below 15 eV, or even more preferably below 10 eV
an ion density of at least 10¹⁰ cm⁻³ at the substrate surface.

2. The reactor (100) of claim 1, wherein said inductively coupled radio-frequency (RF) plasma source comprises said coil (16) and said spiral antenna (17).

3. The reactor (600) of claim 1, wherein said enclosure (3) consists of two parts (3, 3′).

4. The reactor (100; 400; 500; 600) of claim 1, wherein said coil (16) or/and said spiral antenna (17) is/are each operated at a single frequency or at two different frequencies.

5. The reactor (100; 400; 500; 600) of claim 1, wherein said inductive coupled radio-frequency (RF) plasma source provides for a radio-frequency-plasma-assisted chemical vapor deposition inside said enclosure (3).

6. The reactor (100; 400; 500; 600) of claim 1, wherein said means (6) for indirectly heating said substrate are located outside said enclosure (3).

7. The reactor (100; 400; 500; 600) of claim 1, wherein low substrate temperature can be adjusted during epitaxial growth.

8. The reactor (100; 400; 500; 600) of claim 1, wherein said vacuum chamber (2) and hot deposition region (4) can be evacuated to a pressure below 10⁻⁶ mbar, preferably even to pressures below 10⁻⁸ mbar.

9. The reactor (100; 400; 500; 600) of claim 1, wherein a gas distribution ring (13) serves as gas inlet (11).

10. The reactor (100; 400; 500; 600) of claim 1, further comprising an arrangement of coils outside the vessel (1) or enclosure (3) for shaping the plasma generated by said plasma source.

11. The reactor (100; 400; 500; 600) of claim 10, wherein three flat coils (10, 20, 30), arranged in an off-centered configuration, serve as said arrangement of coils.

12. The reactor (100; 400; 500; 600) of claim 10, wherein said arrangement of coils consists of two sets of three flat coils (10, 20, 30), arranged in a Helmholtz or Maxwell configuration.

13. Use of a reactor (100; 400; 500; 600) according to claim 1 for growing a SiC layer on a SiC substrate, whereby said substrate temperature is kept below 1200° C.

14. Use of a reactor (100; 400; 500; 600) according to claim 1 for growing a SiC layer on a Si substrate, whereby said substrate temperature is kept below 1000° C.

15. Use of a reactor (100; 400; 500; 600) according to claim 1 for growing a Si layer on a Si substrate, whereby said substrate temperature is kept below 800° C. and whereby ions with ion energies below 15 eV are employed.

16. Use of a reactor (100; 400; 500; 600) according to claim 1 for growing a Ge layer on a GaAs substrate, whereby said substrate temperature is kept below 500° C.

17. Use of a reactor (100; 400; 500; 600) according to claim 1 for growing a Ge layer on a GaAs substrate, whereby a Ge film is intentionally doped by diffusion from the substrate upon raising the substrate temperature to above 600° C. during or after growth.

18. Use of a reactor (100; 400; 500; 600) according to claim 1 for growing a Ge layer on a Si substrate, whereby said substrate temperature is kept at about 200-300° C.

19. Use of a reactor (100; 400; 500; 600) according to claim 1 for growing a SiGe layer on a Si substrate, whereby said substrate temperature is chosen in accordance with the Ge content.

20. Use of a reactor (100; 400; 500; 600) according to claim 19 for growing a SiGe layer on a Si substrate, whereby the substrate temperature is between 700 and 800° C. for a Ge content of 0 to 0.2, between 600 and 700° C. for a Ge content of 0.2 to 0.4, between 500 and 600° C. for a Ge content of 0.4 to 0.8 and below 500° C. for a Ge content of 0.8 to 1.

21. Method for low-energy plasma-enhanced chemical vapour deposition of an epitaxial semiconductor layer on a semiconductor substrate, said method being carried out in a reactor (100; 400; 500; 600) according to claim 1, comprising the steps:
loading (310) a wafer or substrate onto said susceptor (5),
heating (320) said wafer or substrate to a desired temperature,
performing (325) a low-energy plasma-enhanced chemical vapour deposition by feeding reactive gases into said deposition region (4) while ion energies below about 20 eV, preferably below 15 eV, and a density of at least 10¹⁰ cm⁻³ at the substrate or wafer surface are provided.

22. The method of claim 21, whereby another temperature is adjusted (320) before another a low-energy plasma-enhanced chemical vapour deposition is carried out.

23. The method of claim 21, whereby a plasma wafer or substrate cleaning step is carried out prior to the low-energy plasma-enhanced chemical vapour deposition step.

24. The method of claim 21, whereby an in-situ cleaning step of said deposition region (4) is carried out after said low-energy plasma-enhanced chemical vapour deposition step, by using chlorine or fluorine containing gases.

25. The method of claim 22, whereby after said cleaning step said deposition region (4) is cleaned additionally with a pure hydrogen plasma.

26. The method of claim 21, whereby, before the low-energy plasma-enhanced chemical vapour deposition, walls of the enclosure (3) are pre-coated, with the same material used in the low-energy plasma-enhanced chemical vapour deposition, in order to passivate O₂, F and Cl impurities.
